(19) United States
(12) Patent Application Publication
(10) Pub. No.: US 2017/0243896 A1
(43) Pub. Date: Aug. 24, 2017

(54) ARRAY SUBSTRATE AND LIQUID CRYSTAL DISPLAY DEVICE

(71) Applicant: Wuhan China Star Optoelectronics Technology Co., Ltd., Wuhan (CN)

(72) Inventor: Jiawei ZHANG, Shenzhen (CN)

(73) Assignee: Wuhan China Star Optoelectronics Technology Co., Ltd., Wuhan (CN)

(21) Appl. No.: 15/143,627

(22) Filed: May 1, 2016

(30) Foreign Application Priority Data
Feb. 18, 2016 (CN) 201610089552.3

(51) Int. Cl. H01L 27/12; G02F 1/1333; G02F 1/1362; H01L 29/786; G02F 1/1343

(52) U.S. Cl. CPC H01L 27/1222; H01L 27/124; H01L 29/78633; H01L 29/78618; H01L 29/78609; H01L 29/78675; H01L 29/78645; G02F 1/13439; G02F 1/136209; G02F 1/133345; G02F 2001/133357

(57) ABSTRACT

Provided are an array substrate and a liquid crystal display device. The array substrate includes a base plate and a low temperature poly-silicon layer, a first insulation layer, a gate zone, a second insulation layer, a source zone, a drain zone, a planarization layer, a first transparent conductive layer, a third insulation layer, and a second transparent conductive layer that are arranged on the same side of the base plate. The gate zone covers the first insulation layer. The source zone and the drain zone are respectively connected to two ends of the low temperature poly-silicon layer. The second transparent conductive layer is connected to the drain zone and the second transparent conductive layer includes a plurality of spaced conductive zones.

### BACKGROUND OF THE INVENTION

1. Field of the Invention

The present invention relates to the field of display, and more particularly to an array substrate and a liquid crystal display device.

2. The Related Arts

Display devices, such as a liquid crystal display, are commonly used electronic devices and, due to various advantages, such as low power consumption, small size, and light weight, are prevailing among users. With the progress of the flat panel display technology, demands for liquid crystal displays having high resolutions and low power consumption are raised. Amorphous silicon has relatively low electron mobility, while low temperature poly-silicon allows for manufacture in a low temperature and exhibits higher electron mobility than the amorphous silicon. Further, a complementary metal oxide semiconductor device made of low temperature poly-silicon is useful for providing a liquid crystal display with a higher resolution and lower power consumption. Thus, the low temperature poly-silicon has been under extensive and wide applications and study. In the state of the art, an array substrate of a liquid crystal display device is often composed of a plurality of individual low temperature poly-silicon thin-film transistors that is arranged in an array. The array substrate generally comprises a top transparent conductive layer that is made in the form of an entire unitary piece and such a top transparent conductive layer is usually a sub-pixel electrode. During the manufacture of the sub-pixel electrode, if the sub-pixel electrode and a drain zone are not correctly connected due to various factors, then a sub-pixel corresponding to the sub-pixel electrode may not properly function for displaying. In such a case, a dark spot treatment is applied to the entire sub-pixel electrode that is not correctly connected to the drain zone and as such, the pixel in which the sub-pixel is involved is short of a sub-pixel of one specific color for mixture of color and color deviation (color shifting) may be induced in the color exhibited by the pixel. Further, the image displayed in a liquid crystal display device that involves such an array substrate may be of deteriorated quality.

### SUMMARY OF THE INVENTION

The present invention provides an array substrate, which comprises: a base plate and a low temperature poly-silicon layer, a first insulation layer, a gate zone, a second insulation layer, a source zone, a drain zone, a planarization layer, a first transparent conductive layer, a third insulation layer, and the second transparent conductive layer, which are arranged on the same side of the base plate. The low temperature poly-silicon layer is arranged closer to a surface of the base plate than the first insulation layer, the gate zone, the second insulation layer, the source zone, the drain zone, the planarization layer, the first transparent conductive layer, the third insulation layer, and the second transparent conductive layer. The first insulation layer covers the low temperature poly-silicon layer and the first insulation layer is formed with a first via and a second via respectively corresponding to two opposite ends of the low temperature poly-silicon layer. The gate zone is arranged on a surface of the first insulation layer that is distant from the low temperature poly-silicon layer and the gate zone is arranged to correspond to the low temperature poly-silicon layer. The second insulation layer covers the gate zone and the second insulation layer is formed with a third via and a fourth via, wherein the third via is arranged to correspond to the first via and the fourth via is arranged to correspond to the second via. The source zone has an end in contact with a surface of the second insulation layer that is distant from the gate zone and the source zone is connected, through the first via and the third via, to one of the ends of the low temperature poly-silicon layer; the drain zone has an end in contact with the surface of the second insulation layer that is distant from the gate zone and the drain zone is connected, through the second via and the fourth via, to another one of the ends of the low temperature poly-silicon layer. The planarization layer covers the source zone and the drain zone and the planarization layer is formed with a fifth via that exposes the drain zone. The first transparent conductive layer is disposed on the planarization layer. The third insulation layer covers the first transparent conductive layer and the third insulation layer is formed with a sixth via that corresponds to the fifth via. The second transparent conductive layer is connected, through the fifth via and the sixth via, to the drain zone. The second transparent conductive layer comprises a plurality of conductive zones spaced from each other.

In the above array substrate, the second transparent conductive layer comprises 4n conductive zones that are spaced from each other, wherein n is a positive integer.

In the above array substrate, the first transparent conductive layer comprises a common electrode and the second transparent conductive layer comprises a pixel electrode.

In the above array substrate, the array substrate further comprises a light shielding layer. The light shielding layer is arranged on a surface of the base plate. The low temperature poly-silicon layer, the first insulation layer, the gate zone, the second insulation layer, the source zone, the drain zone, the planarization layer, the first transparent conductive layer, the third insulation layer, and the second transparent conductive layer are arranged, through the light shielding layer, on the same side of the base plate. The light shielding layer is arranged to correspond to the low temperature poly-silicon layer.

In the above array substrate, the array substrate further comprises a light shielding layer and a buffer layer. The light shielding layer is arranged on a surface of the base plate. The buffer layer covers the light shielding layer. The low temperature poly-silicon layer, the first insulation layer, the gate zone, the second insulation layer, the source zone, the drain zone, the planarization layer, the first transparent conductive layer, the third insulation layer, and the second transparent conductive layer are arranged, through the light shielding layer and the buffer layer, on the same side of the base plate. The light shielding layer is arranged to correspond to the low temperature poly-silicon layer.

In the above array substrate, the array substrate further comprises the first ohmic contact layer. The first ohmic contact layer is connected between the source zone and the low temperature poly-silicon layer, where the first ohmic contact layer functions to reduce a contact resistance between the source zone and the low temperature poly-silicon layer.

In the above array substrate, the first ohmic contact layer comprises a first light doping zone and a first heavy doping zone. The first light doping zone is in contact with the low temperature poly-silicon layer. The first heavy doping zone is arranged between the first light doping zone and the source zone and the first heavy doping zone is connected between the first light doping zone and the source zone, wherein the first light doping zone has a doping concentration that is smaller than a doping concentration of the first heavy doping zone.

In the above array substrate, the array substrate further comprises a second ohmic contact layer. The second ohmic contact layer is connected between the drain zone and the low temperature poly-silicon layer, where the second ohmic contact layer functions to reduce a contact resistance between the drain zone and the low temperature poly-silicon layer.

In the above array substrate, the second ohmic contact layer comprises a second light doping zone and a second heavy doping zone. The second light doping zone is in contact with the low temperature poly-silicon layer. The second heavy doping zone is arranged between the second light doping zone and the drain zone and the second heavy doping zone is connected between the second light doping zone and the drain zone, wherein the second light doping zone has a doping concentration that is smaller than a doping concentration of the second heavy doping zone.

The present invention also provides a liquid crystal display device. The liquid crystal display device comprises the above described array substrate.

Compared to the prior art, the second transparent conductive layer of the array substrate of the present invention is connected to the drain zone and the second transparent conductive layer comprises a plurality of conductive zones that is spaced from each other. When some of the conductive zones of the second transparent conductive layer are not correctly connected to the drain zone due to certain factors incurring in a manufacture process of the array substrate, there is no need to subject the entirety of the second transparent conductive layer to dark sport treatment and the dark sport treatment can be conducted only on the conductive zones of the second transparent conductive layer that are not correctly connected to the drain zone. Thus, when sub-pixels of a pixel undergo light mixture, color deviation of a color exhibited may be of an extent smaller than that of the color deviation occurring in the prior art techniques, so that the quality of an image displayed by a liquid crystal display device that involves the array substrate could be improved.

### BRIEF DESCRIPTION OF THE DRAWINGS

To more clearly explain the technical solution proposed in an embodiment of the present invention and that of the prior art, a brief description of the drawings that are necessary for describing embodiments is given as follows. It is obvious that the drawings that will be described below show only some embodiments. For those having ordinary skills of the art, other drawings may also be readily available from these attached drawings without the expense of creative effort and endeavor.

FIG. 1 is a schematic view illustrating a cross-sectional structure of an array substrate according to a preferred embodiment of the present invention; and

FIG. 2 is a schematic view illustrating a liquid crystal display device according to a preferred embodiment of the present invention.

### DETAILED DESCRIPTION OF THE PREFERRED EMBODIMENTS

A clear and complete description will be given to a technical solution of embodiments of the present invention with reference to the attached drawings of the embodiments of the present invention. However, the embodiments so described are only some, but not all, of the embodiments of the present invention. Other embodiments that are available to those having ordinary skills of the art without the expense of creative effort and endeavor are considered belonging to the scope of protection of the present invention.

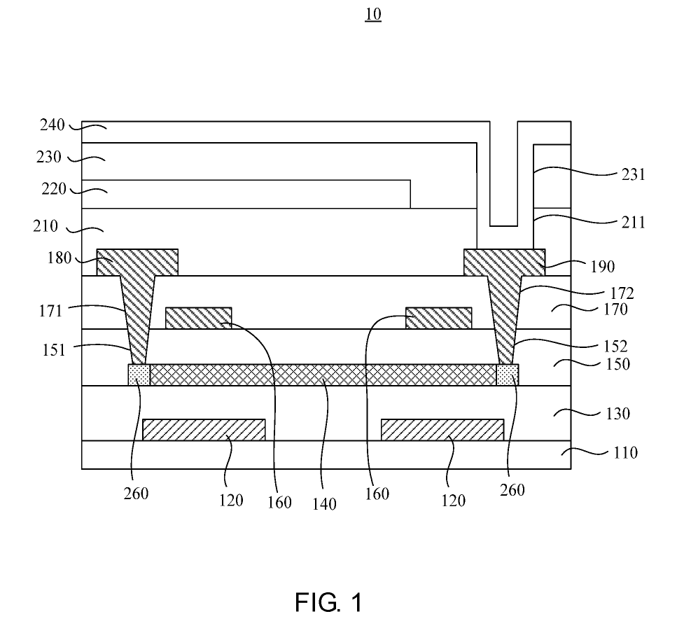

Referring to FIG. 1, FIG. 1 is a schematic view illustrating a cross-sectional structure of an array substrate according to a preferred embodiment of the present invention. The array substrate 100 comprises a base plate 110 and a low temperature poly-silicon layer 140, a first insulation layer 150, a gate zone 160, a second insulation layer 170, a source zone 180, a drain zone 190, a planarization layer 210, a first transparent conductive layer 220, a third insulation layer 230, and the second transparent conductive layer 240, which are arranged on the same side of the base plate 110. The low temperature poly-silicon layer 140 is arranged closer to a surface of the base plate 110 than the first insulation layer 150, the gate zone 160, the second insulation layer 170, the source zone 180, the drain zone 190, the planarization layer 210, the first transparent conductive layer 220, the third insulation layer 230, and the second transparent conductive layer 240. The first insulation layer 150 covers the low temperature poly-silicon layer 140 and the first insulation layer 150 is formed with a first via 151 and a second via 152 respectively corresponding to two opposite ends of the low temperature poly-silicon layer 140. The gate zone 160 is arranged on a surface of the first insulation layer 150 that is distant from the low temperature poly-silicon layer 140 and the gate zone 160 is arranged to correspond to the low temperature poly-silicon layer 140. The second insulation layer 170 covers the gate zone 160 and the second insulation layer 170 is formed with a third via 171 and a fourth via 172, wherein the third via 171 is arranged to correspond to the first via 151 and the fourth via 172 is arranged to correspond to the second via 152. The source zone 180 has an end in contact with a surface of the second insulation layer 170 that is distant from the gate zone 160 and the source zone 180 is connected, through the first via 151 and the third via 171, to one of the ends of the low temperature poly-silicon layer 140; the drain zone 180 has an end in contact with the surface of the second insulation layer 170 that is distant from the gate zone 160 and the drain zone 180 is connected, through the second via 152 and the fourth via 172, to another one of the ends of the low temperature poly-silicon layer 140. The planarization layer 210 covers the source zone 180 and the drain zone 190 and the planarization layer 210 is formed with a fifth via 211 that exposes the drain zone 190. The first transparent conductive layer 220 is disposed on the planarization layer 210. The third insulation layer 230 covers the first transparent conductive layer 220 and the third insulation layer 230 is formed with a sixth via 231 that corresponds to the fifth via 211. The second transparent conductive layer 240 is connected, through the fifth via 211 and the sixth via 231, to the drain zone 180. The second transparent conductive layer 240 comprises a plurality of conductive zones spaced from each other.

The base plate 110 is an insulation plate, which can be, but not limited, to a glass plate or a plastic plate.

Preferably, the second transparent conductive layer 240 comprises 4n conductive zones that are spaced from each other, wherein n is a positive integer.

In the instant embodiment, the first transparent conductive layer 220 is a common electrode and the second transparent conductive layer 240 is a pixel electrode.

In one embodiment, the array substrate 100 further comprises a light shielding layer 120. The light shielding layer 120 is formed on a surface of the base plate 110 and the low temperature poly-silicon layer 140, the first insulation layer 150, the gate zone 160, the second insulation layer 170, the source zone 180, the drain zone 190, the planarization layer 210, the first transparent conductive layer 220, the third insulation layer 230, and the second transparent conductive layer 240 are arranged, through the light shielding layer 120, on the same side of the base plate 110; and the light shielding layer 120 is arranged to correspond to the low temperature poly-silicon layer 140. The light shielding layer 120 functions to prevent a pixel associated with the low temperature poly-silicon thin-film transistor that involves the low temperature poly-silicon layer 140 from leaking light in a direction away from the light shielding layer 120.

In the instant embodiment, the array substrate 100 further comprises a light shielding layer 120 and a buffer layer 130. The light shielding layer 120 is arranged on a surface of the base plate 110 and the buffer layer 130 covers the light shielding layer 120. The low temperature poly-silicon layer 140, the first insulation layer 150, the gate zone 160, the second insulation layer 170, the source zone 180, the drain zone 190, the planarization layer 210, the first transparent conductive layer 220, the third insulation layer 230, and the second transparent conductive layer 240 are arranged, through the light shielding layer 120 and the buffer layer 130, on the same side of the base plate 110 and the light shielding layer 120 is arranged to correspond to the low temperature poly-silicon layer 140. The light shielding layer 120 functions to prevent a pixel associated with the low temperature poly-silicon thin-film transistor that involves the low temperature poly-silicon layer 140 from leaking light in a direction away from the light shielding layer 120. The buffer layer 130 functions to buffer damage of the base plate 110 during a manufacture process of the array substrate 100.

In one embodiment, the buffer layer 130 may comprise a first sub buffer layer (not shown) and a second sub buffer layer (not shown). The first sub buffer layer is arranged closer to the base plate than the second sub buffer layer. The first sub buffer layer comprises a material of silicon nitride (SiNx) and the second sub buffer layer comprises a material of silicon oxide (SiOx). The arrangement of the first sub buffer layer and the second sub buffer layer provides better buffering to the damages of the base plate 110 during a manufacture process of the array substrate 100. And, the first sub buffer layer is formed of a silicon nitride material and in the manufacture of the silicon nitride material, hydrogen (H) elements may be generated to repair the low temperature poly-silicon layer 140 so as to improve electrical performance of the low temperature poly-silicon layer. The second sub buffer layer is formed of a silicon oxide material for improving stress of the second sub buffer layer and preventing detachment of the second sub buffer layer.

In the instant embodiment, the array substrate 100 further comprises a first ohmic contact layer 260. The first ohmic contact layer 260 is connected between the source zone 180 and the low temperature poly-silicon layer 140. The first ohmic contact layer 260 functions to reduce a contact resistance between the source zone 180 and the low temperature poly-silicon layer 140. The first ohmic contact layer 260 comprises a first light doping zone 261 and a first heavy doping zone 262. The first light doping zone 261 is in contact with the low temperature poly-silicon layer 140 and the first heavy doping zone 262 is arranged between the first light doping zone 261 and the source zone 180 and the first heavy doping zone 262 is connected between the first light doping zone 261 and the source zone 180. The first light doping zone 261 has a doping concentration that is smaller than a doping concentration of the first heavy doping zone 262. In the instant embodiment, the first light doping zone 261, the first heavy doping zone 262, and the low temperature poly-silicon layer 140 are on the same layer. The first light doping zone 261 and the first heavy doping zone 262 are doped with the same type of ions, such as being both doped with N type ions. In the instant embodiment, the arrangement of the first light doping zone 261 and the first heavy doping zone 262 helps lower down the contact resistance between the source zone 180 and the low temperature poly-silicon layer 140 and also reduces a leakage current of the low temperature poly-silicon thin-film transistor and improves the electrical performance of the low temperature poly-silicon thin-film transistor.

The array substrate 100 further comprises a second ohmic contact layer 270. the second ohmic contact layer 270 is connected between the drain zone 190 and the low temperature poly-silicon layer 140. The second ohmic contact layer 270 functions to reduce a contact resistance between the drain zone 190 and the low temperature poly-silicon layer 140. The second ohmic contact layer 270 comprises a second light doping zone 271 and a second heavy doping zone 272. The second light doping zone 271 is in contact with the low temperature poly-silicon layer 140 and the second heavy doping zone 272 is arranged between the second light doping zone 271 and the drain zone 190 and the second heavy doping zone 272 is connected between the second light doping zone 271 and the drain zone 190. The second light doping zone 271 has a doping concentration that is smaller than a doping concentration of the second heavy doping zone 272. In the instant embodiment, the second light doping zone 271, the second heavy doping zone 272, and the low temperature poly-silicon layer 140 are on the same layer. The second light doping zone 271 and the second heavy doping zone 272 are doped with the same type of ions, such as being both doped with N type ions. In the instant embodiment, the arrangement of the second light doping zone 271 and the second heavy doping zone 272 helps lower down the contact resistance between the drain zone 190 and the low temperature poly-silicon layer 140 and also reduces a leakage current of the low temperature poly-silicon thin-film transistor and improves the electrical performance of the low temperature poly-silicon thin-film transistor.

Compared to the prior art, the second transparent conductive layer 240 of the array substrate 100 of the present invention is connected to the drain zone 180 and the second transparent conductive layer 240 comprises a plurality of conductive zones that is spaced from each other. When some of the conductive zones of the second transparent conductive layer 240 are not correctly connected to the drain zone 180 due to certain factors incurring in a manufacture process of the array substrate 100, there is no need to subject the entirety of the second transparent conductive layer 240 to dark sport treatment and the dark sport treatment can be conducted only on the conductive zones of the second transparent conductive layer 240 that are not correctly connected to the drain zone 180. Thus, when sub-pixels of a pixel undergo light mixture, color deviation of a color exhibited may be of an extent smaller than that of the color deviation occurring in the prior art techniques, so that the quality of an image displayed by a liquid crystal display device 10 that involves the array substrate 100 could be improved.

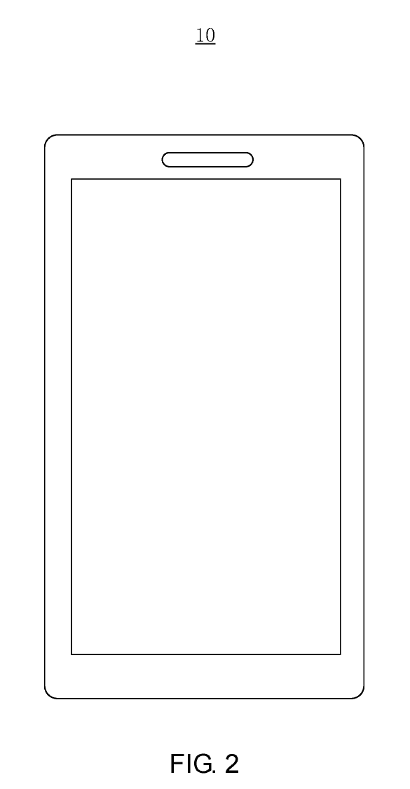

The present invention also provides a liquid crystal display device 10. Reference is also made to FIG. 2, and FIG. 2 is a schematic view illustrating a liquid crystal display device according to a preferred embodiment of the present invention. The liquid crystal display device 10 comprises the array substrate 110 discussed above and repeated description will be omitted herein. The liquid crystal display device 10 can be, but not limited to, a portable electronic device, such as a smart phone, a mobile internet device (MID), an electronic book, a play station portable (PSP), or a personal digital assistant (PDA), or a liquid crystal display.

The present invention has been described with reference to the preferred embodiments. However, it is noted that those skilled in the art would appreciates that various improvements and modifications are still available without departing from the scope of the present invention and such improvements and modifications are considered within the scope of protection of the present invention.

What is claimed is:

1. An array substrate, comprising: a base plate and a low temperature poly-silicon layer, a first insulation layer, a gate zone, a second insulation layer, a source zone, a drain zone, a planarization layer, a first transparent conductive layer, a third insulation layer, and a second transparent conductive layer, which are arranged on the same side of the base plate, the low temperature poly-silicon layer being arranged closer to a surface of the base plate than the first insulation layer, the gate zone, the second insulation layer, the source zone, the drain zone, the planarization layer, the first transparent conductive layer, the third insulation layer, and the second transparent conductive layer, the first insulation layer covering the low temperature poly-silicon layer, the first insulation layer being formed with a first via and a second via respectively corresponding to two opposite ends of the low temperature poly-silicon layer, the gate zone being arranged on a surface of the first insulation layer that is distant from the low temperature poly-silicon layer, the gate zone being arranged to correspond to the low temperature poly-silicon layer, the second insulation layer covering the gate zone, the second insulation layer being formed with a third via and a fourth via, the third via being arranged to correspond to the first via, the fourth via being arranged to correspond to the second via, the source zone having an end in contact with a surface of the second insulation layer that is distant from the gate zone, the source zone being connected, through the first via and the third via, to one of the ends of the low temperature poly-silicon layer, the drain zone having an end in contact with the surface of the second insulation layer that is distant from the gate zone, the drain zone being connected, through the second via and the fourth via, to another one of the ends of the low temperature poly-silicon layer, the planarization layer covering the source zone and the drain zone, the planarization layer being formed with a fifth via that exposes the drain zone, the first transparent conductive layer being disposed on the planarization layer, the third insulation layer covering the first transparent conductive layer, the third insulation layer being formed with a sixth via that corresponds to the fifth via, the second transparent conductive layer being connected, through the fifth via and the sixth via, to the drain zone, wherein the second transparent conductive layer comprises a plurality of conductive zones spaced from each other.

2. The array substrate as claimed in claim 1, wherein the second transparent conductive layer comprises 4n conductive zones that are spaced from each other, wherein n is a positive integer.

3. The array substrate as claimed in claim 1, wherein the first transparent conductive layer comprises a common electrode and the second transparent conductive layer comprises a pixel electrode.

4. The array substrate as claimed in claim 1, wherein the array substrate further comprises a light shielding layer, the light shielding layer being arranged on a surface of the base plate, the low temperature poly-silicon layer, the first insulation layer, the gate zone, the second insulation layer, the source zone, the drain zone, the planarization layer, the first transparent conductive layer, the third insulation layer, and the second transparent conductive layer being arranged, through the light shielding layer, on the same side of the base plate, the light shielding layer being arranged to correspond to the low temperature poly-silicon layer.

5. The array substrate as claimed in claim 1, wherein the array substrate further comprises a light shielding layer and a buffer layer, the light shielding layer being arranged on a surface of the base plate, the buffer layer covering the light shielding layer, the low temperature poly-silicon layer, the first insulation layer, the gate zone, the second insulation layer, the source zone, the drain zone, the planarization layer, the first transparent conductive layer, the third insulation layer, and the second transparent conductive layer being arranged, through the light shielding layer and the buffer layer, on the same side of the base plate; the light shielding layer being arranged to correspond to the low temperature poly-silicon layer.

6. The array substrate as claimed in claim 1, wherein the array substrate further comprises a first ohmic contact layer, the first ohmic contact layer being connected between the source zone and the low temperature poly-silicon layer, wherein the first ohmic contact layer functions to reduce a contact resistance between the source zone and the low temperature poly-silicon layer.

7. The array substrate as claimed in claim 6, wherein the first ohmic contact layer comprises a first light doping zone and a first heavy doping zone, the first light doping zone being in contact with the low temperature poly-silicon layer, the first heavy doping zone being arranged between the first light doping zone and the source zone, and the first heavy doping zone being connected between the first light doping zone and the source zone, wherein the first light doping zone has a doping concentration that is smaller than a doping concentration of the first heavy doping zone.

8. The array substrate as claimed in claim 1, wherein the array substrate further comprises a second ohmic contact layer, the second ohmic contact layer being connected between the drain zone and the low temperature poly-silicon layer, wherein the second ohmic contact layer functions to reduce a contact resistance between the drain zone and the low temperature poly-silicon layer.

9. The array substrate as claimed in claim 8, wherein the second ohmic contact layer comprises a second light doping zone and a second heavy doping zone, the second light doping zone being in contact with the low temperature poly-silicon layer, the second heavy doping zone being arranged between the second light doping zone and the drain zone, and the second heavy doping zone being connected between the second light doping zone and the drain zone, wherein the second light doping zone has a doping concentration that is smaller than a doping concentration of the second heavy doping zone.

10. A liquid crystal display device, comprising the array substrate according to claim 1.
